(19) United States
(12) Patent Application Publication
(10) Pub. No.: US 2019/0025629 A1
(43) Pub. Date: Jan. 24, 2019

(54) DISPLAY DEVICE AND SMART MOBILE DEVICE

(71) Applicant: WUHAN CHINA STAR OPTOELECTRONICS TECHNOLOGY CO., LTD., Wuhan, Hubei (CN)

(72) Inventor: Yong YANG, Shenzhen, Guangdong (CN)

(73) Assignee: Wuhan China Star Optoelectronics Technology Co., Ltd., Wuhan, Hubei (CN)

(21) Appl. No.: 15/735,911

(22) PCT Filed: Sep. 21, 2017
(86) PCT No.: PCT/CN2017/102647

§ 371 Date: Dec. 12, 2017

(30) Foreign Application Priority Data
Jul. 24, 2017 (CN) 201710606767.2

(51) Int. Cl. G02F 1/1345; G02F 1/1335; G02F 1/1368; F21V 8/00; G02F 1/1333

(52) U.S. Cl. CPC G02F 1/13452; G02F 1/133514; G02F 1/133603; G02F 1/133528; G02F 1/1368; H05K 1/147; G02B 6/0055; G02F 1/133308; G02B 6/0085; G02F 2001/133317; G02F 1/133605

(57) ABSTRACT

The present disclosure relates to a display device and a smart mobile device. The display device includes a flexible circuit board, a display module, and a backlight module. The display module includes a color filter (CF) substrate, an array substrate, and a liquid crystal layer between the CF substrate and the array substrate. The backlight module includes a plurality of LEDs arranged in a first area of the display module. A first end of the flexible circuit board is configured with electrical contact points electrically connecting to the array substrate, and a second end of the flexible circuit board is configured with an integrated circuit (IC) chip arranged in a second area of the display module. The first area and the second area are adjacent to each other, or the first area and the second area are spaced apart from each other.

### BACKGROUND OF THE INVENTION

### 1. Field of the Invention

The present disclosure relates to display technology, and more particularly to a display device and a smart mobile device.

### 2. Discussion of the Related Art

In recent years, narrow border technology has become one of the core technologies of various panel manufacturers. By optimizing the visual area on both sides of the non-visible area of the circuit arrangement and space ratio, the borders at two sides of the visible area are narrowed and thus have been recognized by the market.

FIG. 1 is a cross sectional view of one conventional display device. The liquid crystal device (LCD) 1 includes a color filter (CF) substrate 30 having a CF layer 35; an array substrate 10 having a thin film transistor (TFT), gate lines, data lines, and the pixel electrode 15; a liquid crystal layer 40 between the CF substrate 10 and the array substrate 10. A plurality of gate welding electrodes and a plurality of data welding electrodes are respectively configured on a non-active area (NA1) arranged on a top side of the array substrate 10. The gate welding electrodes and the data welding electrodes connect to external driving circuits.

In addition, within the display area (DA) of the array substrate 10, the gate lines and the data lines intersect with each other to define a plurality of pixel areas. The gate lines respectively connect to the gate welding electrodes and extend along a horizontal direction. The data lines respectively connect to the data welding electrodes and extend along a vertical direction.

In addition, at least one TFT is formed at an intersection of the gate line and the data line to form the pixel electrode 15 within each of the pixel areas. The pixel electrode 15 connects to the drain of the corresponding TFT. The CF substrate 30 faces toward the above array substrate 10. The CF layer 35 and the black matrix are formed on the CF substrate 30, and the common electrodes are formed on the whole surface of the CF substrate 30. The CF layer 35 includes a repeated pattern including a red (R), a green (G), and a blue (B), and the pattern corresponding to each pixel areas. The black matrix is formed between the CF patterns, and surrounds the gate lines and the data lines of the array substrate 10. In addition, the black matrix corresponds to the non-active area (NA1) surrounding the display area (DA).

In addition, the liquid crystal layer 40 is configured between the array substrate 10 and the encapsulation structure layer 3. Two sealing patterns 42 are respectively formed within the non-active area (NA1) corresponding to edges of the array substrate 10 and the CF substrate 30 so as to form the LC panel 2.

An outer surface of the array substrate 10 having the LC panel 2 is configured with a backlight module (BLU). A driver (not shown) is configured for driving the LC panel 2 to obtain the LCD 1.

The integrated circuit chip 50 is installed in the non-active area (NA1) of the LC panel 2.

Generally, the integrated circuit chip 50 is arranged on the array substrate 10 to obtain a border non-active area (NA1). That is, the integrated circuit chip 50 is arranged on one side of the array substrate 10, and the integrated circuit chip 50 connects to the data welding electrodes via a FPC 62. By configuring the bonding location of the integrated circuit chip 50, the width of the non-active area (NA1) may be narrowed.

However, with respect to the conventional device, the integrated circuit chip 50 is close to the LED of the BLU. Due to the heat dissipation of the integrated circuit chip 50, such configuration may cause the backlight module malfunction.

### SUMMARY

The present disclosure relates to a display device and a smart mobile device. By configuring the relative location between the LED and the IC chip, the heat dissipation issue caused to the LED may be eliminated.

In one aspect, a display device includes: a flexible circuit board, a display module, and a backlight module, wherein the display module includes a color filter (CF) substrate, an array substrate, and a liquid crystal layer between the CF substrate and the array substrate; the backlight module includes a plurality of LEDs arranged in a first area of the display module, a first end of the flexible circuit board is configured with electrical contact points electrically connecting to the array substrate, a second end of the flexible circuit board is configured with an integrated circuit (IC) chip arranged in a second area of the display module, the first area and the second area are adjacent to each other, or the first area and the second area are spaced apart from each other, the CF substrate includes a polarizer, a glass sheet, and a color filter arranged in sequence; the array substrate includes the polarizer and the glass sheet, and at least one pixel electrode and at least one thin film transistor (TFT) are configured on the glass sheet; and the backlight module includes a silver reflective film.

In another aspect, a display device includes: a flexible circuit board, a display module, and a backlight module, wherein the display module includes a color filter (CF) substrate, an array substrate, and a liquid crystal layer between the CF substrate and the array substrate; the backlight module includes a plurality of LEDs arranged in a first area of the display module, a first end of the flexible circuit board is configured with electrical contact points electrically connecting to the array substrate, a second end of the flexible circuit board is configured with an integrated circuit (IC) chip arranged in a second area of the display module, the first area and the second area are adjacent to each other, or the first area and the second area are spaced apart from each other.

In another aspect, a smart mobile device includes any one of the above display device.

In view of the above, by configuring the relative location between the LEDs and the IC chip, the heat dissipation issue caused to the LED may be eliminated. Thus, the stability of the display device may be enhanced, and the life cycle of the display device may be extended.

### BRIEF DESCRIPTION OF THE DRAWINGS

FIG. 1 is a schematic view of one conventional display device.

FIG. 2 is a schematic view of the display device in accordance with one embodiment of the present disclosure.

FIG. 3 is a schematic view of the display device in accordance with another embodiment of the present disclosure.

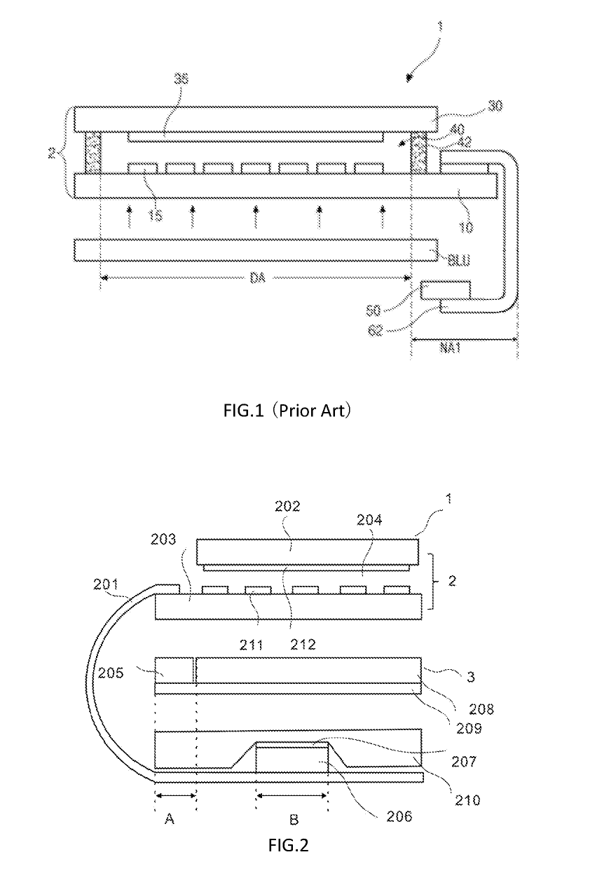

### DETAILED DESCRIPTION OF THE EMBODIMENTS

Embodiments of the invention will now be described more fully hereinafter with reference to the accompanying drawings, in which embodiments of the invention are shown.

FIG. 2 is a schematic view of the display device in accordance with one embodiment of the present disclosure. The display device 1 includes a flexible circuit board 201, a display module 2, and a backlight module 3. The display module 2 includes a CF substrate 202, an array substrate 203, and a liquid crystal layer 204 between the CF substrate 202 and the array substrate 203.

In one embodiment, the backlight module 3 is an edge-type backlight module. The backlight module 3 includes at least one LED 205 arranged within a first area (A) of the display module, and the first area is perpendicular to the display module. The backlight module 3 further includes a light guiding plate 208 and a silver reflective film 209.

The CF substrate 202 includes a CF layer 212. The array substrate 203 includes at least one TFT (not shown), at least one gate line (not shown), at least one data line (not shown), and a pixel cell 211.

A first end of the flexible circuit board 201 electrically connects to the pixel cell 211, and a second end of the flexible circuit board 201 is configured with an IC chip 206. The IC chip 206 is arranged within a second area (B) of the display module 2, and the second area is perpendicular to the display module.

In one embodiment, the backlight module 3 is an edge-type backlight module. The LEDs 205 of the backlight module 3 are arranged in a rim area of the backlight module 3, i.e., the first area (A). The IC chip 206 is arranged in a middle area of the backlight module 3, i.e., the second area (B). A gap is configured between the first area (A) and the second area (B). At this moment, the LEDs 205 and the IC chip 206 are spaced apart from each other along a vertical direction so as to eliminate the heat dissipation impact toward the LED 205 caused by the IC chip 206.

Further, the display device 1 is also configured with a middle frame 210. The IC chip 206 is arranged between the middle frame 210 and the flexible circuit board 201. As the middle frame 210 may contribute to the heat isolation, the impact toward the LED 205 caused by the IC chip 206 may be further reduced.

Further, a buffer layer 207 is configured between the IC chip 206 and the middle frame 210, which prevents the IC chip 206 from being damaged by external forces.

Further, one end of the flexible circuit board 201 is configured with electrical contact points (not shown). The IC chip 206 and the electrical contact points are configured on the same side of the flexible circuit board 201 so as to facilitate the printing and the manufacturing process of the flexible circuit board 201.

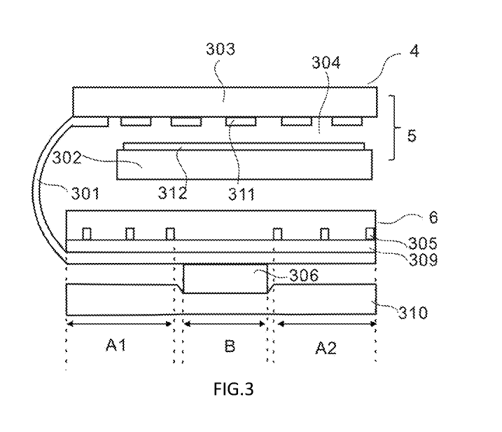

FIG. 3 is a schematic view of the display device in accordance with another embodiment of the present disclosure. The display device 4 includes a flexible circuit board 301, a display module 5, and a backlight module 6. The display module 5 includes a CF substrate 302, an array substrate 303, and a liquid crystal layer 304 between the CF substrate 302 and the array substrate 303. The CF substrate 302 of the display module 5 is arranged on an outer side of the array substrate 303.

In the embodiment, the backlight module 6 is a direct-lit backlight module. The backlight module 6 includes LEDs 305. The LEDs 305 are arranged within the first area (A1, A2). The backlight module 6 further includes a silver reflective film 309.

The CF substrate 302 includes a CF layer 312. The array substrate 303 includes a CF layer 312. The array substrate 303 includes at least one TFT (not shown), at least one gate line (not shown), at least one data line (not shown), and at least one pixel cell 311.

A first end of the flexible circuit board 301 electrically connects to the pixel cell 311, and a second end of the flexible circuit board 301 is configured with an IC chip 306. The IC chip 306 is arranged within a second area (B) of the display module 5.

In one embodiment, the backlight module 6 is a direct-lit backlight module. The LEDs 305 of the backlight module 6 are arranged in the first area (A1, A2) of the backlight module 6. The IC chip 306 is arranged in a middle area of the backlight module 6, i.e., the second area (B). A gap is configured between the first area (A1, A2) and the second area (B). At this moment, the LEDs 305 and the IC chip 206 are spaced apart from each other along a vertical direction so as to eliminate the heat dissipation impact toward the LED 305 caused by the IC chip 306.

In other embodiments, the first (A1, A2) may be adjacent to the second area (B), that is, first ends of the first area (A1) and the second area (B) are overlapped, and second ends of the first area (A2) and the second area (B) are overlapped. This may ensure that the LEDs 305 and the IC chip 306 are spaced apart from each other along a vertical direction so as to eliminate the heat dissipation impact toward the LED 305 caused by the IC chip 306.

Further, one end of the flexible circuit board 301 is configured with electrical contact points (not shown). The IC chip 306 and the electrical contact points are configured on the same side of the flexible circuit board 301 so as to facilitate the printing and the manufacturing process of the flexible circuit board 301.

In one embodiment, the electrical contact points and the IC chip 206 are configured on an outer side of the flexible circuit board 301, so as to facilitate the printing and the manufacturing process of the flexible circuit board 301. Also, the flexible circuit board 301 may provide the heat isolation function.

Further, the display device 4 is also configured with a middle frame 310. As the middle frame 310 may contribute to the heat isolation, the impact toward the LED 305 caused by the IC chip 206 may be further reduced. In addition, the thickness of the middle frame 310 may be less than the thickness of the middle frame 210 in the previous embodiment.

The display device may be adopted in the smart mobile device, including cellular phones and tablets.

In view of the above, by configuring the relative location between the LEDs and the IC chip, the heat dissipation issue caused to the LED may be eliminated. Thus, the stability of the display device may be enhanced, and the life cycle of the display device may be extended.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A display device, comprising:
a flexible circuit board, a display module, and a backlight module, wherein the display module comprises a color filter (CF) substrate, an an⁻ay substrate, and a liquid crystal layer between the CF substrate and the array substrate;
the backlight module comprising a plurality of LEDs arranged in a first area of the display module, the first area being perpendicular to the display module, a first end of the flexible circuit board is configured with electrical contact points electrically connecting to the array substrate, a second end of the flexible circuit board is configured with an integrated circuit (IC) chip arranged in a second area of the display module, the second area being perpendicular to the display module, the first area and the second area are adjacent to each other, or the first area and the second area are spaced apart from each other, the CF substrate comprises a polarizer, a glass sheet, and a color filter arranged in sequence; the array substrate comprises a polarizer and a glass sheet, and a pixel electrode and a thin film transistor (TFT) are configured on the glass sheet; and the backlight module comprises a silver reflective film.

2. A display device, comprising:
a flexible circuit board, a display module, and a backlight module, wherein the display module comprises a color filter (CF) substrate, an array substrate, and a liquid crystal layer between the CF substrate and the array substrate;
the backlight module comprising a plurality of LEDs arranged in a first area of the display module, the first area being perpendicular to the display module, a first end of the flexible circuit board is configured with electrical contact points electrically connecting to the array substrate, a second end of the flexible circuit board is configured with an integrated circuit (IC) chip arranged in a second area of the display module, the second area being perpendicular to the display module, the first area and the second area are adjacent to each other, or the first area and the second area are spaced apart from each other.

3. The display device as claimed in claim 2, wherein the backlight module is an edge-type backlight module.

4. The display device as claimed in claim 3, wherein the backlight module comprises a light guiding plate and a silver reflective film.

5. The display device as claimed in claim 3, wherein the display device further comprises a middle frame, and the IC chip is configured on an outer side of the middle frame.

6. The display device as claimed in claim 3, wherein the display device further comprises a buffer layer configured between the IC chip and the middle frame.

7. The display device as claimed in claim 3, wherein the IC chip and the electrical contact points are configured on the same side of the flexible circuit board.

8. The display device as claimed in claim 2, wherein the backlight module is a direct-lit backlight module.

9. The display device as claimed in claim 8, wherein the backlight module comprises a silver reflective film.

10. The display device as claimed in claim 8, wherein the CF substrate of the display module is arranged on an outer side of the array substrate.

11. The display device as claimed in claim 8, wherein the display device further comprises a middle frame, and the IC chip is configured on an internal side of the middle frame.

12. A smart mobile device, comprising:
a flexible circuit board, a display module, and a backlight module, wherein the display module comprises a color filter (CF) substrate, an array substrate, and a liquid crystal layer between the CF substrate and the array substrate;
the backlight module comprising a plurality of LEDs arranged in a first area of the display module, the first area being perpendicular to the display module, a first end of the flexible circuit board is configured with electrical contact points electrically connecting to the array substrate, a second end of the flexible circuit board is configured with an integrated circuit (IC) chip arranged in a second area of the display module, the second area being perpendicular to the display module, the first area and the second area are adjacent to each other, or the first area and the second area are spaced apart from each other.

13. The smart mobile device as claimed in claim 12, wherein the backlight module is an edge-type backlight module.

14. The smart mobile device as claimed in claim 13, wherein the backlight module comprises a light guiding plate and a silver reflective film.

15. The smart mobile device as claimed in claim 13, wherein the display device further comprises a middle frame, and the IC chip is configured on an outer side of the middle frame.

16. The smart mobile device as claimed in claim 13, wherein the display device further comprises a buffer layer configured between the IC chip and the middle frame.

17. The smart mobile device as claimed in claim 13, wherein the IC chip and the electrical contact points are configured on the same side of the flexible circuit board.

18. The smart mobile device as claimed in claim 12, wherein the backlight module is a direct-lit backlight module.

19. The smart mobile device as claimed in claim 18, wherein the CF substrate of the display module is arranged on an outer side of the array substrate.

20. The smart mobile device as claimed in claim 18, wherein the display device further comprises a middle frame, and the IC chip is configured on an internal side of the middle frame.
